(19) United States
(12) Patent Application Publication
(10) Pub. No.: US 2025/0253710 A1
(43) Pub. Date: Aug. 7, 2025

(54) RESONATOR STRUCTURE AND WIRELESS POWER TRANSMISSION APPARATUS INCLUDING SAME

(71) Applicant: SAMSUNG ELECTRONICS CO., LTD., Suwon-si (KR)

(72) Inventors: Beomwoo GU, Suwon-si (KR); Jaehyun PARK, Suwon-si (KR); Jaeseok PARK, Suwon-si (KR); Kangho BYUN, Suwon-si (KR); Sungku YEO, Suwon-si (KR)

(73) Assignee: SAMSUNG ELECTRONICS CO., LTD., Suwon-si (KR)

(21) Appl. No.: 19/184,473

(22) Filed: Apr. 21, 2025

Related U.S. Application Data
(63) Continuation of application No. PCT/KR2023/015541, filed on Oct. 10, 2023.

(30) Foreign Application Priority Data
Oct. 21, 2022 (KR) 10-2022-0136546

(51) Int. Cl. H02J 50/12; H02J 50/00; H02J 50/80; H05K 7/20

(52) U.S. Cl. CPC H02J 50/12; H02J 50/005; H02J 50/80; H05K 7/20172

(57) ABSTRACT

A wireless power transmission device includes a resonator configured to transmit wireless power to another device and includes at least one coil and at least one capacitor, an internal space formed inside the at least one coil, and a power transmission circuit disposed in the internal space.

### CROSS-REFERENCE TO RELATED APPLICATIONS

This application is a continuation application of International Application No. PCT/KR2023/015541, filed on Oct. 10, 2023, which claims priority to Korean Patent Application No. 10-2022-0136546, filed on Oct. 21, 2022, in the Korean Intellectual Property Office, the disclosures of which are incorporated by reference herein in their entireties.

### BACKGROUND

### 1. Field

The present disclosure relates generally to wireless power transmission devices, and more particularly, to a resonator structure and a wireless power transmission device including the same.

### 2. Description of Related Art

Wireless charging technology may utilize wireless power transmission and reception techniques. For example, wireless power transmission and reception may refer to a technology of automatically charging a battery of a portable device by placing the portable device on a wireless power transmission device (e.g., a charging pad), without connecting the portable device to a separate charging connector. Such a wireless charging technology may enhance and/or assist in the waterproofing of the portable device by eliminating the need for a connector for supplying power to the portable device. In addition, since a wired charger may be unnecessary, such a technology may have the advantage of increasing the portability of the portable device.

Along with advancements in wireless charging technology, methods may be studied to supply power from a single electronic device (e.g., a wireless power transmission device) to various other electronic devices (e.g., wireless power reception devices) and charge the other electronic devices. Wireless charging technology may include, but not be limited to, an electromagnetic induction method using coils, a resonance method using resonance, a radio wave radiation (e.g., radio frequency (RF) and/or microwave radiation) method that may convert electrical energy into electromagnetic waves and transfer the electromagnetic waves, or the like.

Recently, wireless charging technology based on electromagnetic induction or resonance may have been adopted for electronic devices such as, but not limited to, smartphones, personal digital assistants (PDAs), tablet computers, smart devices, wearable devices, or any other similar functioning devices. For example, when a power transmitting unit (PTU) (e.g., a wireless power transmission device) and a power receiving unit (PRU) (e.g., a smartphone or wearable electronic device) come into contact or are within a certain distance, the battery of the PRU may be charged through electromagnetic induction or electromagnetic resonance between the PTU's transmission coil and the PRU's reception coil.

### SUMMARY

One or more example embodiments of the present disclosure provide a wireless power transmission device including a resonator structure that reduces losses in a magnetic field generated by the coil, when compared to related wireless power transmission devices.

According to an aspect of the present disclosure, a wireless power transmission device includes a resonator configured to transmit wireless power to another device and includes at least one coil and at least one capacitor, an internal space formed inside the at least one coil, and a power transmission circuit disposed in the internal space.

According to an aspect of the present disclosure, a wireless power transmission device includes a resonator configured to transmit wireless power to another device and includes at least one coil and at least one capacitor, an internal space formed inside the at least one coil, and a power transmission circuit disposed in the internal space. At least a portion of the at least one coil forms a closed-loop shape.

Additional aspects may be set forth in part in the description which follows and, in part, may be apparent from the description, and/or may be learned by practice of the presented embodiments.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1A illustrates a block diagram of a wireless power transmission device and an electronic device, according to an embodiment of the disclosure;

FIG. 1B illustrates a block diagram of a wireless power transmission device and a plurality of electronic devices, according to an embodiment of the disclosure;

FIG. 2A illustrates a wireless power transmission device and an electronic device, according to an embodiment of the disclosure;

FIG. 2B illustrates a detailed block diagram of a power transmission circuit and a power reception circuit, according to an embodiment of the disclosure;

FIG. 3 is a perspective view illustrating a wireless power transmission device and at least one electronic device, according to an embodiment of the disclosure;

FIG. 4A is a distribution diagram of the magnetic field generated by a wireless power transmission device, according to a comparative example;

FIG. 4B is a distribution diagram of the magnetic field generated by a wireless power transmission device, according to an embodiment of the disclosure;

FIG. 5A is a perspective view illustrating at least one capacitor, according to an embodiment of the disclosure;

FIG. 5B is a perspective view illustrating at least one capacitor, according to an embodiment of the disclosure;

FIG. 6 is a plan view of a wireless power transmission device, according to an embodiment of the disclosure;

FIG. 7 is a cross-sectional view for describing the inside of a wireless power transmission device, according to an embodiment of the disclosure;

FIG. 8 is a diagram for describing a cooling fan of the wireless power transmission device, according to an embodiment of the disclosure;

FIG. 9 is a plan view of a wireless power transmission device, according to an embodiment of the disclosure;

FIG. 10A is a cross-sectional view for describing the inside of a wireless power transmission device, according to an embodiment of the disclosure;

FIG. 10B is a cross-sectional view for describing the inside of a wireless power transmission device, according to an embodiment of the disclosure;

FIG. 11A is a circuit diagram of a wireless power transmission device, according to an embodiment of the disclosure;

FIG. 11B is a circuit diagram of a wireless power transmission device, according to an embodiment of the disclosure;

FIG. 12 is a perspective view of a wireless power transmission device, according to an embodiment of the disclosure;

FIG. 13 is an exploded perspective view of a wireless power transmission device, according to an embodiment of the disclosure;

FIG. 14 is a circuit diagram of a wireless power transmission device, according to an embodiment of the disclosure;

FIG. 15 is a perspective view of a wireless power transmission device, according to an embodiment of the disclosure;

FIG. 16 is an exploded view of a wireless power transmission device, according to an embodiment of the disclosure;

FIG. 17 is an enlarged view of portion A of FIG. 16, according to an embodiment of the disclosure; and

FIG. 18 is a circuit diagram of a wireless power transmission device, according to an embodiment of the disclosure.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

As used herein, when an element or layer is referred to as “covering” or “surrounding” another element or layer, the element or layer may cover at least a portion of the other element or layer, where the portion may include a fraction of the other element or may include an entirety of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

As used herein, each of the terms “BaTiO₃”, and the like may refer to a material made of elements included in each of the terms and is not a chemical formula representing a stoichiometric relationship.

Hereinafter, various embodiments of the present disclosure are described with reference to the accompanying drawings.

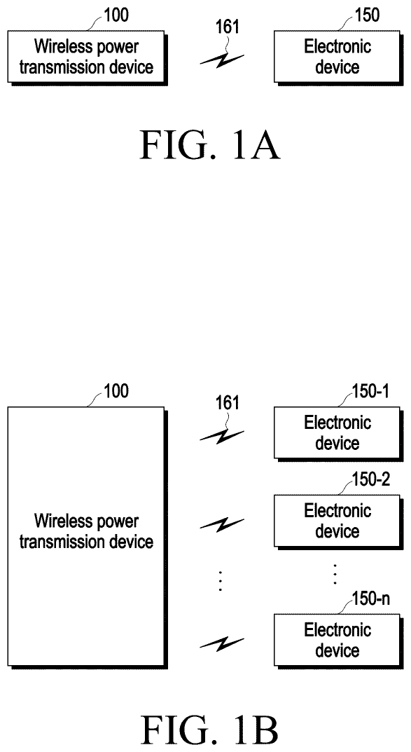

FIG. 1A illustrates a block diagram of a wireless power transmission device and an electronic device, according to an embodiment of the disclosure. FIG. 1B illustrates a block diagram of a wireless power transmission device and a plurality of electronic devices, according to an embodiment of the disclosure.

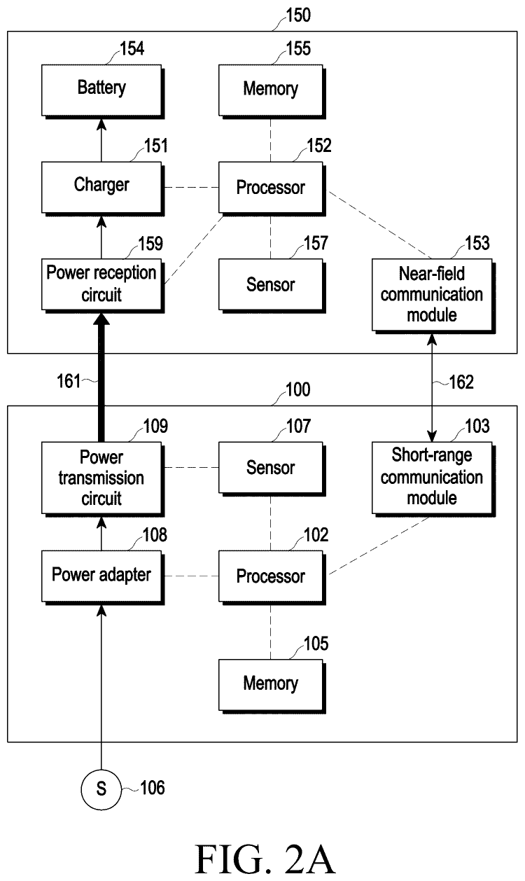

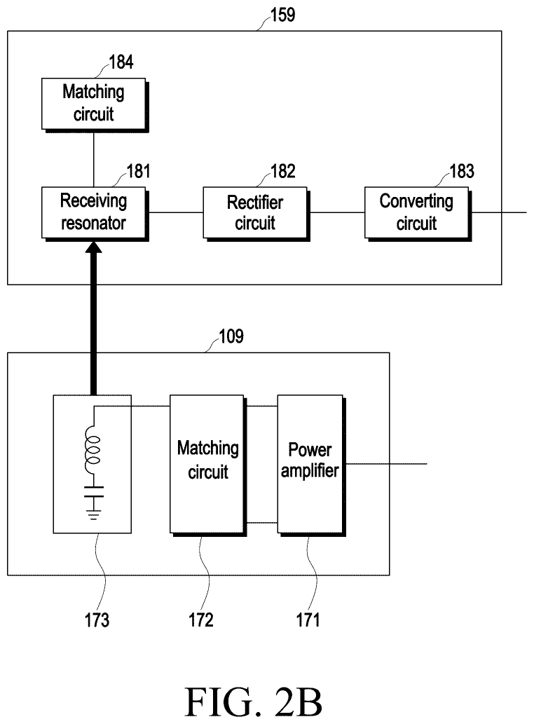

The embodiments of FIGS. 1A and 1B may be combined with the embodiments of FIGS. 2A to 18.

Referring to FIG. 1A, a wireless power transmission device 100, according to an embodiment, may wirelessly transmit power 161 to a wireless power reception device 150 (hereinafter referred to as “electronic device 150”). The wireless power transmission device 100 may transmit power 161 to the electronic device 150 according to various charging schemes. For example, the wireless power transmission device 100 may transmit power 161 based on an induction scheme. When the wireless power transmission device 100 adopts the induction scheme, the wireless power transmission device 100 may include, for example, a power source, a direct current (DC)-alternating current (AC) conversion circuit, an amplifying circuit, an impedance matching circuit, at least one capacitor, at least one coil, and a communication modulation circuit. The at least one capacitor together with the at least one coil may constitute a resonance circuit. The wireless power transmission device 100 may be implemented in a scheme defined according to the Wireless Power Consortium (WPC) standard (also referred to as the Qi standard).

Alternatively or additionally, for example, the wireless power transmission device 100 may transmit power 161 based on a resonance scheme. In this case, the wireless power transmission device 100 may include, for example, a power source, a DC-AC conversion circuit, an amplifying circuit, an impedance matching circuit, at least one capacitor, at least one coil, an out-of-band (OOB) communication module, or a short-range communication module (e.g., a Bluetooth™ Low Energy (BLE) short-range communication module). The at least one capacitor and the at least one coil may form a resonance circuit. The wireless power transmission device 100 may be implemented in a scheme defined according to the Alliance for Wireless Power (A4WP) standard (also referred to as the AirFuel Alliance (AFA) standard). The wireless power transmission device 100 may include a coil capable of generating a time-varying magnetic field may change in magnitude over time when alternating current flows, based on the resonance and/or the induction scheme.

The process of the wireless power transmission device 100 generating the magnetic field may be described as the wireless power transmission device 100 outputting power 161 and/or wirelessly transmitting power. Alternatively or additionally, the electronic device 150 may include a coil that may generate an induced electromotive force by the time-varying magnetic field formed around the coil. The process of the electronic device 150 generating the induced electromotive force through the coil may be described as the electronic device 150 receiving power 161 and/or wirelessly receiving power 161.

The wireless power transmission device 100, according to an embodiment of the disclosure, may communicate with the electronic device 150. For example, the wireless power transmission device 100 may communicate with the electronic device 150 according to an in-band scheme. The wireless power transmission device 100 or the electronic device 150 may change the load (or load impedance), for example, based on an on/off keying modulation scheme to transmit data. The wireless power transmission device 100 and/or the electronic device 150 may determine data transmitted from a counterpart device by measuring a change in load (or load impedance) based on a variation in the magnitude of the current, voltage, and/or power of the coil.

Alternatively or additionally, for example, the wireless power transmission device 100 may communicate with the electronic device 150 according to an out-of-band (OOB) scheme. The wireless power transmission device 100 and/or the electronic device 150 may use a short-range communication module (e.g., a BLE communication module) provided separately from the coil or patch antenna to transmit and/or receive data. The frequency band of the wireless power and the frequency band of the short-range communication module are separated from each other. For example, in the AirFuel standard, the frequency band for wireless power may be 6.78 megahertz (MHz), and the frequency band for the short-range communication module may be 2.4 gigahertz (GHz).

When the wireless power transmission device 100 and/or the electronic device 150 performs a specific operation, it may indicate that various hardware components included in the wireless power transmission device 100 and/or the electronic device 150 (e.g., a processor, coil, or patch antenna) perform the specific operation. Alternatively or additionally, when the wireless power transmission device 100 and/or the electronic device 150 performs a specific operation, it may indicate that the processor controls other hardware to execute the specific operation. Furthermore, the wireless power transmission device 100 and/or the electronic device 150 performing a specific operation may indicate that an instruction for performing the specific operation, stored in a storage circuit (e.g., memory) of the wireless power transmission device 100 and/or the electronic device 150, is executed, thus causing the processor or other hardware to perform the specific operation.

As illustrated in FIG. 1B, the wireless power transmission device 100 may establish a wireless power link with a plurality of electronic devices (e.g., a first electronic device 150-1, a second electronic device 150-2, to an n-th electronic device 150-n, where n is a positive integer greater than one (1)). The plurality of electronic devices 150-1 to 150-n may include, for example, at least one of a portable communication device (e.g., a smartphone), a wearable device (e.g., a watch, wireless earphones, an augmented reality (AR) device, a virtual reality (VR) device, or the like), a portable multimedia device (e.g., a tablet computer, or a laptop computer), a personal digital assistant (PDA), a portable multimedia player (PMP), a camera, portable medical device, or a home appliance (e.g., a television (TV)). In addition, various other types of electronic devices may also be applicable.

The wireless power transmission device 100 may wirelessly transmit power 161 to the plurality of electronic devices 150-1 to 150-n. For example, the wireless power transmission device 100 may transmit power to the plurality of electronic devices 150-1 to 150-n through a resonance method. When the wireless power transmission device 100 adopts the resonance method, the power transmission and reception distance between the wireless power transmission device 100 and the plurality of electronic devices 150-1 to 150-n may be one (1) meter or less, and preferably 30 centimeters (cm) or less. However, the present disclosure is not limited in this regard.

In another example, the wireless power transmission device 100 may transmit power to the plurality of electronic devices 150-1 to 150-n through an induction method. When the wireless power transmission device 100 adopts the induction method, the power transmission and reception distance between the wireless power transmission device 100 and the plurality of electronic devices 150-1 to 150-n may preferably be 10 cm or less. However, the present disclosure is not limited in this regard.

According to some embodiments, at least one of the plurality of electronic devices 150-1 to 150-n may receive power from the wireless power transmission device 100 via the resonance method, and at least one other of the plurality of electronic devices 150-1 to 150-n may receive power from the wireless power transmission device 100 via the induction method.

The processor included in the wireless power transmission device 100 may control the transmission of a predetermined power 161 wirelessly to a plurality of electronic devices 150-1 to 150-n. For example, the predetermined power transmitted to the plurality of electronic devices 150-1 to 150-n may be set to a level sufficient to operate (e.g., wake up) the processor included in the plurality of electronic devices 150-1 to 150-n. The predetermined power 161 may be set by considering various information about the plurality of electronic devices 150-1 to 150-n, such as the various types of the plurality of electronic devices 150-1 to 150-n, the different power requirements of the plurality of electronic devices 150-1 to 150-n, various voltage or current information related to the power for the plurality of electronic devices 150-1 to 150-n, various ratings (e.g., root mean square (RMS) power values or the like) of the plurality of electronic devices 150-1 to 150-n, and the orientation information (e.g., positional information) of the plurality of electronic devices 150-1 to 150-n. The magnitude of the power 161 transmitted to the plurality of electronic devices 150-1 to 150-n may be substantially similar and/or the same for each of the plurality of electronic devices 150-1 to 150-n, however, the present disclosure is not limited in this regard. For example, various electronic devices of the plurality of electronic devices 150-1 to 150-n may be transmitted different magnitudes of the power 161.

The wireless power transmission device 100 may perform communication with each of the plurality of electronic devices 150-1 to 150-n simultaneously or sequentially, as well as, selectively or independently. Each of the plurality of electronic devices 150-1 to 150-n may transmit and/or receive data with the wireless power transmission device 100 according to either an in-band and/or out-of-band scheme.

The data communicated between the wireless power transmission device 100 and the plurality of electronic devices 150-1 to 150-n may be used to control power reception for each of the plurality of electronic devices 150-1 to 150-n. Alternatively or additionally, the data may include various information about the plurality of electronic devices 150-1 to 150-n.

FIG. 2A illustrates a wireless power transmission device and an electronic device, according to an embodiment. FIG. 2B illustrates a detailed block diagram of a power transmission circuit and a power reception circuit, according to an embodiment.

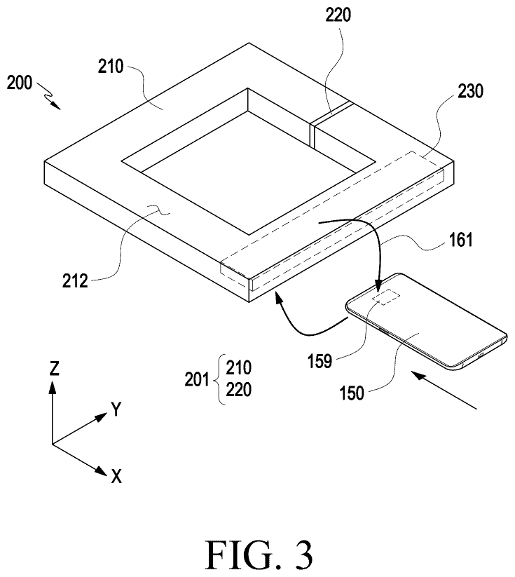

The embodiments of FIGS. 2A and 2B may be combined with the embodiments of FIGS. 1A and 1B or the embodiments of FIGS. 3 to 18.

Referring to FIG. 2A, a wireless power transmission device 100 (e.g., the wireless power transmission devices 100 of FIGS. 1A and 1B), according to an embodiment, may include at least one of a processor 102, a short-range communication module 103, a memory 105, a power adapter 108, or a power transmission circuit 109. An electronic device 150 (e.g., the electronic devices 150 of FIGS. 1A to 1B), according to an embodiment, may include at least one of a charger 151, a processor 152, a short-range communication module 153, a battery 154, a memory 155, or a power reception circuit 159.

The power transmission circuit 109, according to an embodiment, may wirelessly transmit power 161 based on at least one of an induction method, a resonance method, or an electromagnetic wave method. Example configurations of the power transmission circuit 109 and the power reception circuit 159 are described with reference to FIG. 2B. The processor 102 may control the overall operation of the wireless power transmission device 100. For example, the processor 102 may determine whether to transmit power 161, control the magnitude of power 161, or control at least one function of the electronic device 150 (e.g., initiating or stopping charging). The processor 102 or processor 152 may be implemented as various circuits capable of performing operations, such as, but not limited to, a general-purpose processor (e.g., a central processing unit (CPU), a microprocessor, a microcontroller unit (MCU), or an field programmable gate array (FPGA), without limitation on the type.

The processor 102 may transmit and/or receive data 162 with the electronic device 150 via the short-range communication module 103. The data communicated between the processor 102 and the electronic device 150 may be used for controlling wireless power transmission and/or reception. The short-range communication module 103 and the near-field communication module 153 may, for example, be implemented as out-of-band communication modules (e.g., Bluetooth™ communication modules (e.g., BT, BLE) or NFC communication modules) and/or as load modulation communication modules in an in-band communication scheme.

In the case of an in-band communication scheme, the load modulation communication module may include, for example, a switch connected directly to the coil of the power reception circuit 159 and/or through another component, and a dummy load (e.g., a dummy resistor or a dummy capacitor) connected to the coil directly or via another component through the switch. The load modulation communication module may detect information based on changes in the voltage or current applied to the coil in the power transmission circuit 109, as detected during the on/off process of the switch. The power adapter 108 may receive power from the power source 106 and provide the power to the power transmission circuit 109. The power adapter 108 may, for example, serve as a power interface and, based on the implementation of various embodiments, may not be included in the wireless power transmission device 100.

The power reception circuit 159, according to an embodiment, may wirelessly receive power from the power transmission circuit 109 based on at least one of an induction method, a resonance method, or an electromagnetic waves method. The power reception circuit 159 may perform power processing including, but not limited to, rectifying the received AC power waveform into a DC waveform, converting the voltage, or regulating the power. The charger 151 may charge the battery 154 using the received regulated power (e.g., DC power). The charger 151 may adjust at least one of the voltage or current of the received power and deliver the adjusted power to the battery 154. The battery 154 may store the power and subsequently deliver it to other hardware. In an embodiment, a power management integrated circuit (PMIC) may receive power from the power reception circuit 159 and deliver the power to other hardware and/or components, and/or receive power from the battery 154 and supply the received power to other hardware and/or components. Alternatively or additionally, the charger 151 may be provided as part of the PMIC.

The processor 152 may control the overall operation of the electronic device 150. The memory 155 may store instructions for performing the overall operations of the electronic device 150. The memory 105 may store instructions for performing the overall operations of the wireless power transmission device 100 and/or may store a lookup table and/or mathematical formula information representing the relationship between the information obtained through the short-range communication module 103 and the power level to be transmitted. The memory 105 or the memory 155 may be implemented in various forms, such as read-only memory (ROM), random access memory (RAM), or flash memory, without limitation on the implementation type.

Referring to FIG. 2B, the power transmission circuit 109 may include a power amplifier 171, a matching circuit 172 (or matching network), and a transmission resonance circuit 173. The power amplifier 171 or inverter circuit may convert DC power received from the power adapter 108 into AC power. The frequency of the AC power may be set to 100 kHz to 205 kHz, or 6.78 MHz, according to standards, however the present disclosure is not limited to these values. The matching circuit 172 may enable the power transmission circuit 109 and the power reception circuit 159 to be impedance-matched by adjusting at least one of the capacitance or reactance of the circuit connected to the transmission resonance circuit 173 under the control of the processor 102. The transmission resonance circuit 173 may include at least one coil and at least one capacitor. When AC power (or current) is applied to the transmission resonance circuit 173, a magnetic field with a time-varying magnitude may be generated from the transmission resonance circuit 173, thereby enabling the output and/or transmission of power in the form of an electromagnetic field to the power reception circuit 159 of the electronic device 150. In the receiving resonator 181 of the power reception circuit 159, an induced electromotive force may be generated by the surrounding time-varying magnetic field, allowing the power reception circuit 159 to receive power wirelessly. In an embodiment, the receiving resonator 181 may include at least one coil and at least one capacitor. The rectifier circuit 182 may rectify the received AC waveform power. The converting circuit 183 may adjust the voltage of the rectified power and deliver the adjusted power to the PMIC or charger. The power reception circuit 159 may further include a regulator, or alternatively, the converting circuit 183 may be replaced by a regulator. The matching circuit 184 may enable the power transmission circuit 109 and the power reception circuit 159 to be impedance-matched by changing at least one of the capacitance or reactance of the circuit connected to the receiving resonator 181 under the control of the processor 152.

Referring again to FIG. 2A, the wireless power transmission device 100, according to an embodiment of the disclosure, may include at least one sensor 107.

The at least one sensor 107 may be a sensor that may measure the voltage and/or current of the wireless power transmission device 100. Through the at least one sensor 107, the wireless power transmission device 100 may measure the output impedance of the power amplifier 171 and/or the input impedance of the transmission resonance circuit 173 (e.g., the impedance of the signal input from the matching circuit 172 to the transmission resonance circuit 173). For example, by measuring the transmission voltage and transmission current using the sensor 107, the wireless power transmission device 100 may monitor power consumption and detect changes in the input impedance of the transmission resonance circuit 173. Upon detecting an impedance change, the wireless power transmission device 100 may determine whether the electronic device 150 receiving wireless power is mounted and/or removed, detect foreign object presence, or monitor changes in the amount of received power. For example, if one of multiple electronic devices 150 being charged by the wireless power transmission device 100 moves closer to the wireless power transmission device 100, the received power and efficiency of other electronic devices may decrease. The processor 102 may control the transmission and efficiency of wireless power to the multiple electronic devices 150 by considering the detected impedance change, following a predefined algorithm or based on user-input commands.

The electronic device 150, according to an embodiment of the disclosure, may include at least one sensor 157.

For example, the electronic device 150 may detect movement of the electronic device 150 through at least one sensor 157 (e.g., a motion sensor). The motion sensor for detecting movement may include, but not be limited to, at least one of a gyro sensor, accelerometer, angular velocity sensor, gravity sensor, geomagnetic sensor, infrared sensor, or the like. For example, the electronic device 150 may measure the output voltage from the rectifier circuit 182 using at least one sensor 157. Based on the measured output voltage, the electronic device 150 may determine changes in its position relative to the wireless power transmission device 100 (e.g., whether the electronic device 150 has moved closer to and/or farther from the resonator). The data sensed through the sensor 157 may be provided to the processor 152, and the data received by the processor 152 may be provided to the wireless power transmission device 100 via the short-range communication module 153.

The number and arrangement of components of the wireless power transmission device 100 and the electronic device 150 shown in FIG. 2A are provided as an example. In practice, there may be additional components, fewer components, different components, or differently arranged components than those shown in FIG. 2A. Furthermore, two or more components shown in FIG. 2A may be implemented within a single component, or a single component shown in FIG. 2A may be implemented as multiple, distributed components. Alternatively or additionally, a set of (one or more) components shown in FIG. 2A may be integrated with each other, and/or may be implemented as an integrated circuit, as software, and/or a combination of circuits and software.

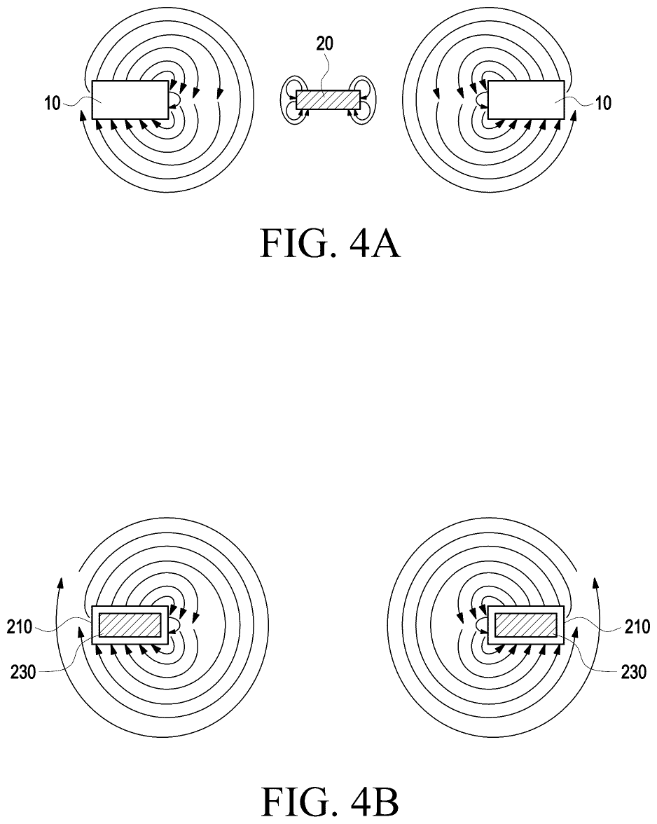

FIG. 3 is a perspective view illustrating a wireless power transmission device and at least one electronic device, according to an embodiment of the disclosure. FIG. 4A is a distribution diagram of the magnetic field generated by the wireless power transmission device, according to a comparative example. FIG. 4B is a distribution diagram of the magnetic field generated by the wireless power transmission device, according to an embodiment of the disclosure.

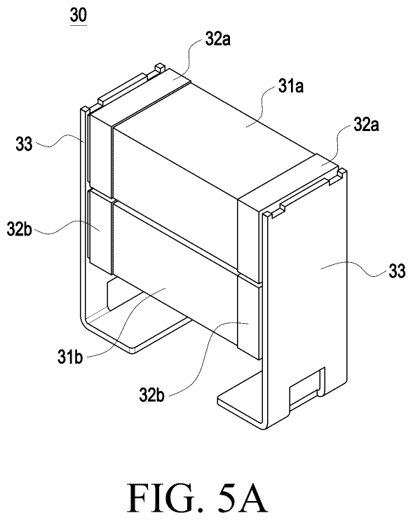

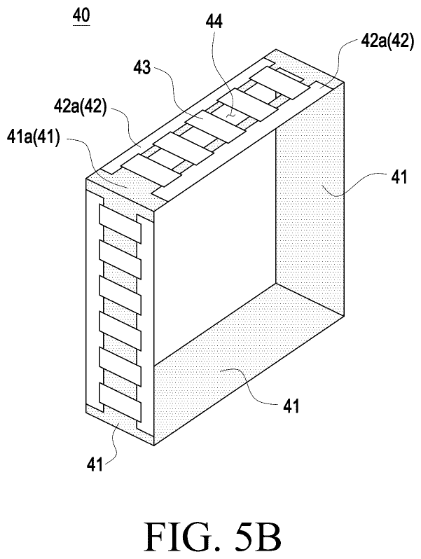

The embodiments of FIGS. 3 to 4B may be combined with the embodiments of FIGS. 1A to 2B or the embodiments of FIGS. 5A to 18.

Referring to FIG. 3, the wireless power transmission device 200 may include a resonator 201 and a power transmission circuit 230.

According to an embodiment, the resonator 201 may include at least one coil 210 and at least one capacitor 220. According to an embodiment, the at least one coil 210 may be formed in a loop or ring shape, however, the present disclosure is not limited to these shapes. For example, the at least one coil 210 may include at least one inductor.

According to an embodiment, the at least one coil 210 may have a shape in which at least a portion is severed or spaced apart from an adjacent portion. In an embodiment, the at least one capacitor 220 may be positioned at the severed or spaced-apart portion.

According to an embodiment, the at least one coil 210 may include an internal space 212 formed within the at least one coil 210.

According to an embodiment, the internal space 212 may accommodate various electronic components (e.g., the processor 102, the short-range communication module 103, or the memory 105 of FIG. 2A).

According to an embodiment, the power transmission circuit 230 (e.g., the power transmission circuit 109 in FIG. 2A) may be arranged in the internal space 212.

According to an embodiment, when current is applied to the at least one coil 210, the current may flow only on the surface (e.g., outer surface) of the at least one coil 210 due to a skin effect. According to an embodiment, since no current flows on the inside (or inner surface) of the at least one coil 210, magnetic flux may be offset in the internal space 212.

According to an embodiment, the wireless power transmission device 200 may adopt a resonance method for power transmission to an electronic device 150 located nearby. According to an embodiment, the wireless power transmission device 200 may perform power output and/or transmission to the electronic device 150 using the resonator 201.

According to an embodiment, the power transmission circuit 230 of the wireless power transmission device 200 may output power 161 in the form of an electromagnetic field to the electronic device 150 through the at least one coil 210. According to an embodiment, the electronic device 150 may receive the power 161 in the form of an electromagnetic field through the receiving resonator (e.g., the receiving resonator 181 in FIG. 2B) of the power reception circuit 159 and charge the battery (e.g., the battery 154 in FIG. 2A).

Referring to FIG. 4A, a wireless power transmission device, according to a comparative example, is illustrated, showing the distribution of the magnetic field (or electromagnetic field) generated when the power transmission circuit 20 is arranged outside, rather than in the internal space of at least one coil 10. For example, when the power transmission circuit 20 (or a component including the power transmission circuit) is disposed outside the at least one coil 10, the magnetic field formed by the at least one coil 10 may experience losses due to the metal components of the power transmission circuit 20. Alternatively or additionally, the magnetic field generated by the at least one coil 10 may generate noise in the components of the power transmission circuit 20, and consequently, the power transmission circuit 20 may need to have a separate shielding structure.

Referring to FIG. 4B, a wireless power transmission device (e.g., the wireless power transmission device 200 in FIG. 3), according to an embodiment of the disclosure, is illustrated, showing the distribution of the magnetic field generated when the power transmission circuit 230 is disposed within the internal space of at least one coil 210 (e.g., the at least one coil 210 in FIG. 3). For example, when the power transmission circuit 230 (e.g., the power transmission circuit 230 in FIG. 3) (or a component including the power transmission circuit) is placed inside the at least one coil 210, it may be observed that, in the region of the magnetic field formed by the at least one coil 210, no loss of the magnetic field occurs compared to FIG. 4A, as the power transmission circuit 230 is not placed outside the region. Alternatively or additionally, since the magnetic field generated by the at least one coil 210 does not cause noise in the components of the power transmission circuit 230, the power transmission circuit 230 may not need a separate shielding structure.

FIG. 5A is a perspective view illustrating at least one capacitor, according to an embodiment of the disclosure. FIG. 5B is a perspective view illustrating at least one capacitor, according to an embodiment of the disclosure.

The embodiments of FIGS. 5A and 5B may be combined with the embodiments of FIGS. 1A to 4B or FIGS. 6 to 18.

Referring to FIG. 5A, at least one capacitor 30 may include at least one body in which a dielectric layer and internal electrodes may be alternately arranged, at least one external electrode connected to the internal electrodes, or at least one bracket 33 connected to the at least one external electrode.

According to an embodiment, the internal electrodes may include nickel (Ni) grains, ceramics distributed within the nickel (Ni) grains, or at least one coating layer. According to an embodiment, the raw material forming the dielectric layer may be barium titanate (BaTiO₃) powder but may also be composed of various materials capable of ensuring sufficient capacitance.

According to an embodiment, at least one capacitor 30 may include a first body 31a and a second body 31b. Each of the first body 31a and the second body 31b may include the internal electrodes and/or the dielectric layer. According to an embodiment, the at least one external electrode may include a pair of first external electrodes 32a disposed on the first body 31a and a pair of second external electrodes 32b disposed on the second body 31b. The pair of first external electrodes 32a may be connected to the internal electrodes of the first body 31a. The pair of second external electrodes 32b may be connected to the internal electrodes of the second body 31b.

According to an embodiment, at least one bracket 33 may be connected to the first external electrode 32a and the second external electrode 32b. The at least one bracket 33 may supply power applied through at least one coil (e.g., at least one coil 210 of FIG. 3) to the first external electrode 32a and/or the second external electrode 32b, or may supply power output through the first external electrode 32a or the second external electrode 32b to at least one coil (e.g., at least one coil 210 of FIG. 3).

According to an embodiment, at least one bracket 33 may be welded to a spaced-apart portion of at least one coil (e.g., at least one coil 210 of FIG. 3), however, the present disclosure is not limited thereto.

In an embodiment, at least one capacitor 30 may further include a cover that may protect the components of at least one capacitor 30 from external impact.

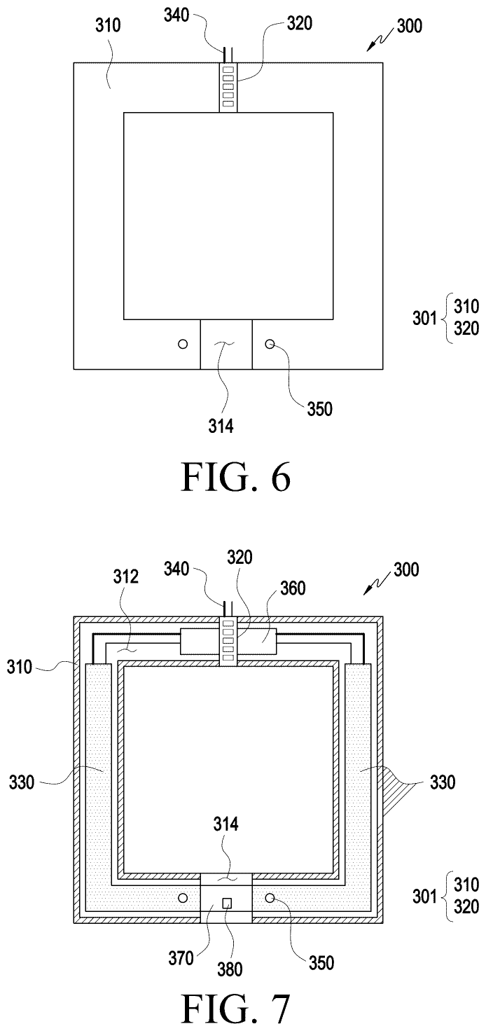

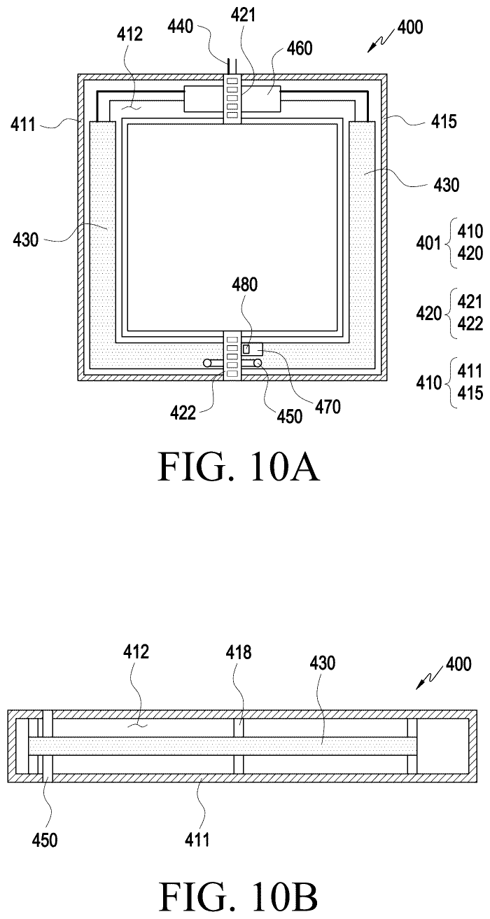

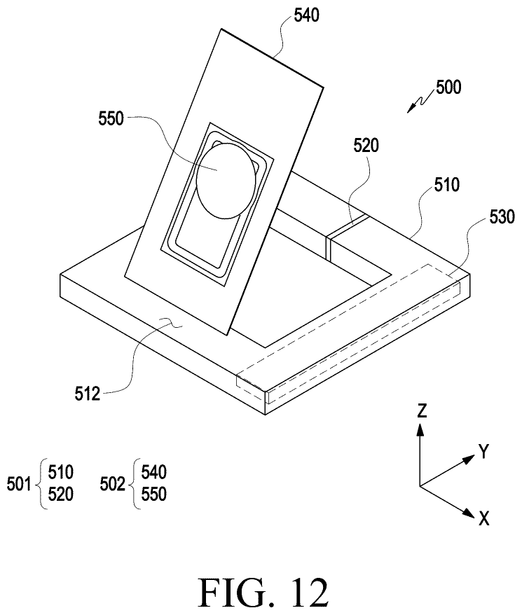

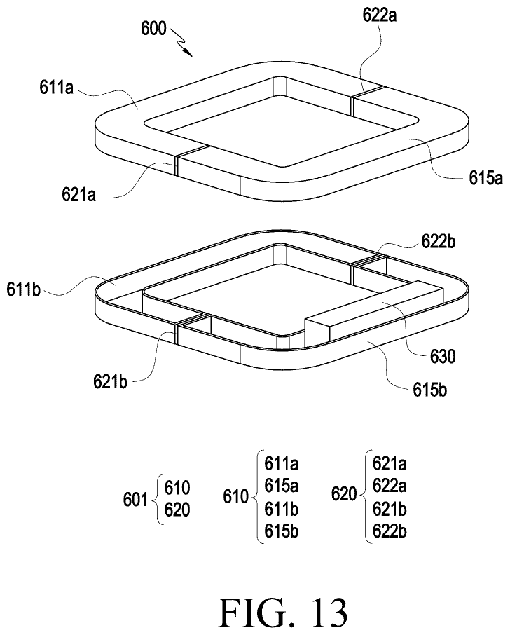

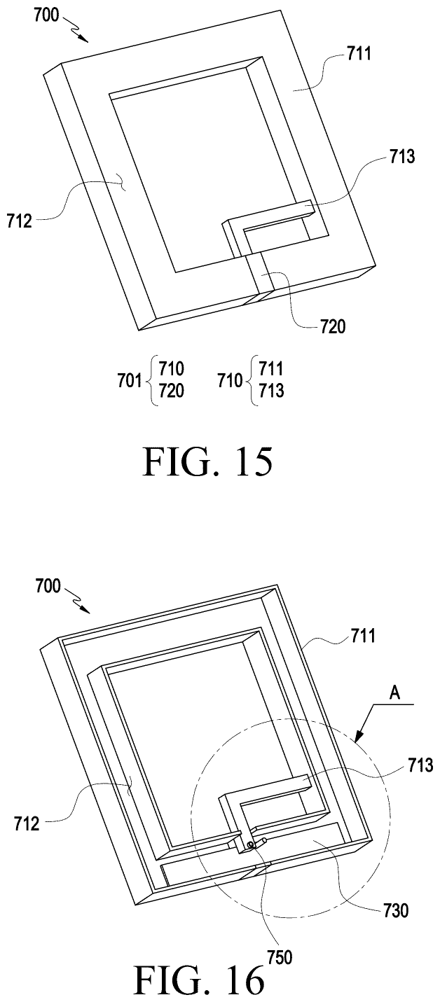

At least one capacitor 220 of FIG. 3, at least one capacitor 320 of FIGS. 6 to 8, at least one capacitor 420 of FIGS. 9 and 10A, at least one capacitor 520 of FIG. 12, at least one capacitor 620 of FIG. 13, or at least one capacitor 720 of FIG. 15 may include and/or may be similar in many respects to the at least one capacitor 30 of FIG. 5A.

Referring to FIG. 5B, at least one capacitor 40 may include a plurality of circuit boards 41, a plurality of solder pads 42, or a plurality of capacitor electrodes 43.

According to an embodiment, each of a plurality of circuit boards 41 may include a printed circuit board (PCB). The plurality of circuit boards 41 may be sequentially connected. As shown in FIG. 5B, the plurality of circuit boards 41 may be connected to form a rectangular cross-sectional shape; however, the connection structure of the plurality of circuit boards 41 is not limited thereto.

According to an embodiment, each of a plurality of solder pads 42 may be disposed and/or mounted on the plurality of circuit boards 41. A pair of solder pads 42 may be mounted on each of the plurality of circuit boards 41. For example, considering one circuit board 41a from among the plurality of circuit boards 41 as an example, solder pads 42a may be disposed and/or mounted on both side edges of the circuit board 41a.

According to an embodiment, each of the plurality of solder pads 42 may be welded to a spaced-apart portion of at least one coil (e.g., at least one coil 210 of FIG. 3), however, the present disclosure is not limited thereto.

According to an embodiment, each of the plurality of capacitor electrodes 43 may be electrically connected to a pair of solder pads 42. For example, the plurality of solder pads 42 may provide power applied from at least one coil (e.g., at least one coil 210 of FIG. 3) to the plurality of capacitor electrodes 43, or may supply power output from the plurality of capacitor electrodes 43 to at least one coil (e.g., at least one coil 210 of FIG. 3).

In an embodiment, at least one capacitor 40 may further include a cover that may protect the components of at least one capacitor 40 from external impact.

At least one capacitor 220 of FIG. 3, at least one capacitor 320 of FIGS. 6 to 8, at least one capacitor 420 of FIGS. 9 and 10A, at least one capacitor 520 of FIG. 12, at least one capacitor 620 of FIG. 13, or at least one capacitor 720 of FIG. 15 may include and/or may be similar in many respects to the at least one capacitor 40 of FIG. 5B.

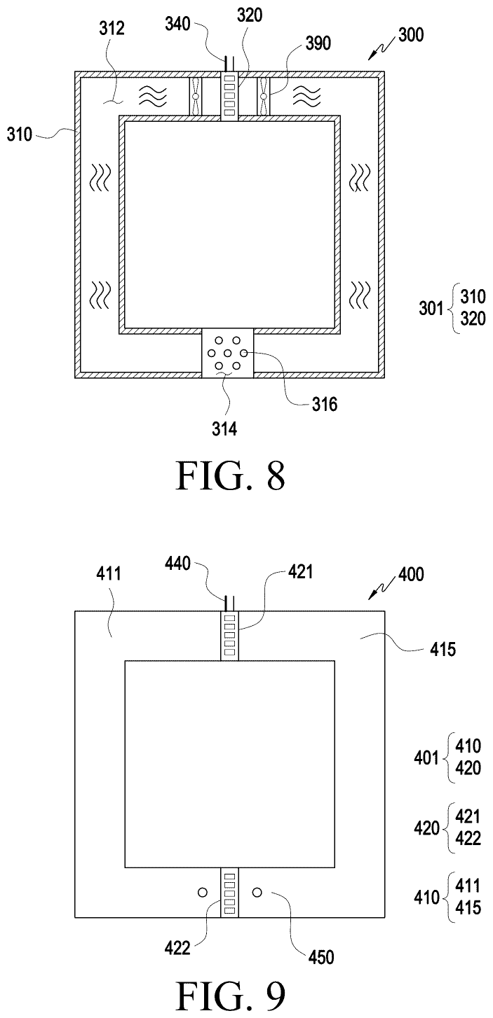

FIG. 6 is a plan view of a wireless power transmission device, according to an embodiment of the disclosure. FIG. 7 is a cross-sectional view illustrating the inside of a wireless power transmission device, according to an embodiment of the disclosure. FIG. 8 is a view illustrating a cooling fan of the wireless power transmission device, according to an embodiment of the disclosure.

The embodiments of FIGS. 6 to 8 may be combined with the embodiments of FIGS. 1A to 5B or FIGS. 9 to 18.

Referring to FIGS. 6 to 8, a wireless power transmission device 300 (e.g., the wireless power transmission device 100 of FIGS. 1A to 2B, or the wireless power transmission device 200 of FIG. 3) may include a resonator 301 that includes at least one coil 310 and at least one capacitor 320.

Referring to FIGS. 6 to 8, the wireless power transmission device 300 may include a DC power supply unit 340. According to an embodiment, the DC power supply unit 340 may be electrically connected to a power adapter 300 (e.g., the power adapter 108 in FIG. 2A) of the wireless power transmission device and may supply the DC power (or power) provided from a power source (e.g., the power source 106 in FIG. 2A) to the power adapter.

According to an embodiment, at least one coil 310 may include an internal space 312 (e.g., the internal space 312 in FIG. 3). According to an embodiment, a mounting space 314 may be formed in a part of at least one coil 310 to accommodate a control circuit 370. For example, the mounting space 314 may be defined as a disconnected portion or spaced-apart portion of at least one coil 310.

According to an embodiment, a control circuit 370 may be a circuit board (e.g., PCB) on which at least one antenna 380 (e.g., the short-range communication module 103 of FIG. 2A), a processor (e.g., the processor 102 of FIG. 2A), memory (e.g., the memory 105 of FIG. 2A), or a sensor (e.g., the sensor 107 of FIG. 2A) is disposed (or mounted).

According to an embodiment, the control circuit 370 may be electrically connected to an AC power output unit (AC power supply or AC power output) 350 disposed on at least one coil 310. Additionally, the control circuit 370 may be electrically connected to a power transmission circuit 330.

According to an embodiment, the wireless power transmission device 300 may further include at least one filter 360. The at least one filter 360 may be disposed inside at least one coil 310 and may be positioned adjacent to at least one capacitor 320.

According to an embodiment, the at least one filter 360 may be and/or may include an electromagnetic interference (EMI) filter that blocks an electric field generated by at least one capacitor 320 from entering the inside of at least one coil 310; however, the present disclosure is not limited thereto.

According to an embodiment, the wireless power transmission device 300 may further include at least one cooling fan 390 positioned in the internal space 312 of at least one coil 310.

According to an embodiment, at least one cooling fan 390 may create an airflow within the internal space 312. For example, at least one cooling fan 390 may be positioned adjacent to at least one capacitor 320. According to an embodiment, at least one cooling fan 390 may generate an airflow within the internal space 312 in a direction from the capacitor 320 toward the mounting space 314. Accordingly, heat generated from components positioned within the internal space 312 may be discharged to the outside of the wireless power transmission device 300 through an exhaust hole 316 formed in the mounting space 314.

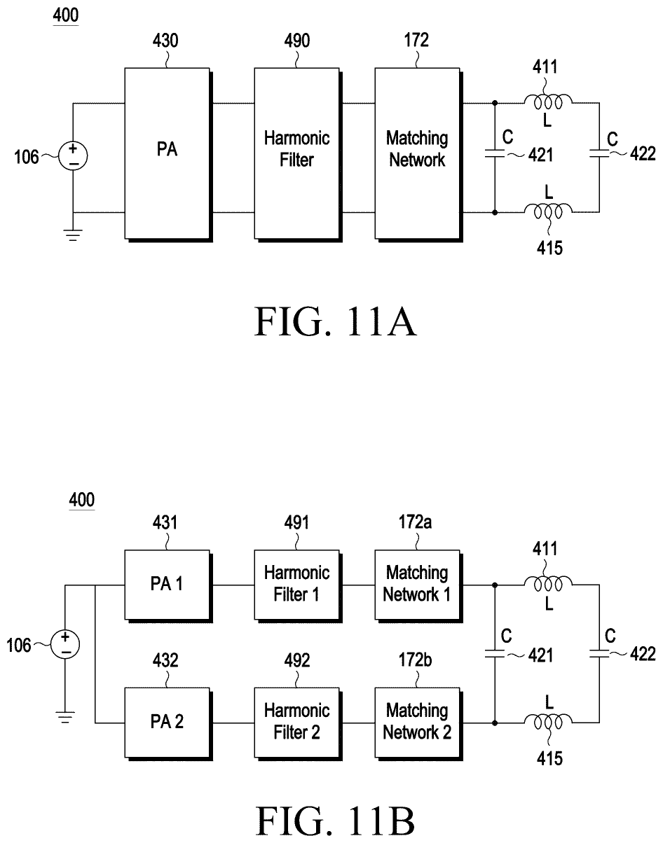

FIG. 9 is a plan view of a wireless power transmission device, according to an embodiment of the disclosure. FIG. 10A is a cross-sectional view illustrating the inside of a wireless power transmission device, according to an embodiment of the disclosure. FIG. 10B is a cross-sectional view illustrating the inside of a wireless power transmission device, according to an embodiment of the disclosure. FIG. 11A is a circuit diagram of a wireless power transmission device, according to an embodiment of the disclosure. FIG. 11B is a circuit diagram of a wireless power transmission device, according to an embodiment of the disclosure.

The embodiments of FIGS. 9 to 11B may be combined with the embodiments of FIGS. 1A to 8 or FIGS. 12 to 18.

Referring to FIGS. 9 to 11B, the wireless power transmission device 400 may include a resonator 401 comprising at least one coil 410 and at least one capacitor 420, a power transmission circuit 430, a DC power supply unit 440, an AC power output unit 450, at least one filter 460, a control circuit 470, and at least one antenna 480.

Referring to FIGS. 9 to 11B, at least one coil 410 may include a first coil 411 and a second coil 415. The first coil 411 may be connected to the second coil 415 through a first capacitor 421 and a second capacitor 422. The at least one capacitor 420 may include the first capacitor 421 and a second capacitor 422, spaced apart from the first capacitor 421.

According to an embodiment, the first capacitor 421 may be positioned adjacent to at least one filter 460, and the second capacitor 422 may be positioned adjacent to the control circuit 470. Additionally, the first capacitor 421 and the second capacitor 422 may be arranged on at least one coil 410 to face in opposite directions, however, the present disclosure is not limited thereto. According to an embodiment, the first capacitor 421 may be positioned adjacent to the DC power supply unit 440, and the second capacitor 422 may be positioned adjacent to the AC power output unit 450.

According to an embodiment, the control circuit 470 may have at least one antenna 480 (e.g., the short-range communication module 103 in FIG. 2A) disposed (or mounted) on it. According to embodiment, at least one antenna 480 may be configured to radiate an antenna signal through a gap between at least one coil 410 where the second capacitor 422 is positioned.

According to an embodiment, the power transmission circuit 430 may be positioned in the internal space 412 formed within at least one coil 410. The power transmission circuit 430 may include a power amplifier.

According to an embodiment, the first capacitor 421 and the second capacitor 422 may be arranged in parallel, however, the present disclosure is not limited thereto.

Referring to FIG. 10B, the wireless power transmission device 400 may further include a spacer 418. According to an embodiment, the spacer 418 may be formed of a non-metal material, however, the present disclosure is not limited thereto.

According to an embodiment, the spacer 418 may be configured to support the power transmission circuit 430 disposed within the internal space 412 of the at least one coil 410. For example, the spacer 418 may support one portion of the power transmission circuit 430 and another portion facing the opposite direction from the one portion, thereby restricting the power transmission circuit 430 from being physically connected to the at least one coil 410.

According to an embodiment, the AC power output unit 450 may electrically connect the power transmission circuit 430 to the at least one coil 410.

FIGS. 11A and 11B are circuit diagrams of the wireless power transmission device 400 illustrated in FIGS. 9 to 10B.

Referring to FIG. 11A, the wireless power transmission device 400 may include a power transmission circuit 430 that receives power (or electrical energy) provided by a power source (e.g., the power source 106 of FIG. 2A).

According to an embodiment, the wireless power transmission device 400 may include a harmonic filter 490 for removing harmonic waves (e.g., harmonics) of the circuit of the wireless power transmission device 400 or a matching circuit (e.g., the matching circuit 172 of FIG. 2B) (or a matching network).

According to an embodiment, the first coil 411 and the second coil 415 may be arranged in series.

According to an embodiment, the first capacitor 421 and the second capacitor 422 may be arranged in parallel.

According to an embodiment, the at least one coil 410 and the second capacitor 422 may be arranged in parallel with the first capacitor 421 with respect to the power source 106.

Referring to FIG. 11B, the wireless power transmission device 400 may include a power transmission circuit 430 that receives power (or electrical energy) provided by a power source (e.g., the power source 106 of FIG. 2A).

According to an embodiment, the power transmission circuit of the wireless power transmission device 400 (e.g., the power transmission circuit 430 of FIGS. 9 to 10B) may include a first power transmission circuit 431 and a second power transmission circuit 432 arranged in parallel with the first power transmission circuit 431. The first power transmission circuit 431 may include a power amplifier (PA). The second power transmission circuit 432 may include a power amplifier.

According to an embodiment, the wireless power transmission device 400 may include a first harmonic filter 491 and a second harmonic filter 492 for removing harmonic waves (e.g., harmonics) of the circuit of the wireless power transmission device 400, a first matching circuit 172a (e.g., the matching circuit 172 of FIG. 2B) (or a matching network), or a second matching circuit 172b (e.g., the matching circuit 172 of FIG. 2B) (or a matching network).

According to an embodiment, the first capacitor 421 and the second capacitor 422 may be arranged in parallel.

According to an embodiment, the at least one coil 410 and the second capacitor 422 may be arranged in parallel with the first capacitor 421 with respect to the power source 106.

FIG. 12 is a perspective view of a wireless power transmission device, according to an embodiment of the disclosure.

The embodiment of FIG. 12 may be combined with the embodiments of FIGS. 1A to 11B or the embodiments of FIGS. 13 to 18.

Referring to FIG. 12, the wireless power transmission device 500 may include a first resonator 501 and a second resonator 502.

The first resonator 501 of FIG. 12 may be a resonator as described, for example, in FIGS. 1A to 11B, however, the present disclosure is not limited thereto.

According to an embodiment, the second resonator 502 may be detachably coupled to the first resonator 501, however, the present disclosure is not limited thereto. For example, the second resonator 502 may be defined and referred to as a detachable resonator. For example, the second resonator 502 may refer to a resonator that may be used in a coupled state with the first resonator 501 or in a detached state from the first resonator 501.

According to an embodiment, the second resonator 502 may include a base housing 540 and at least one coil 550 disposed in the base housing 540. The second resonator 502 may optionally include at least one capacitor.

According to an embodiment, the second resonator 502 may electromagnetically couple with at least one electronic device located around the wireless power transmission device 500 to transmit wireless power. According to an embodiment, at least one coil 550 of the second resonator 502 may electromagnetically couple with at least one coil 510 of the first resonator 501. For example, the second resonator 502 may provide wireless power supplied from the first resonator 501 to an electronic device.

According to an embodiment, the second resonator 502, being configured to be detachably coupled to the first resonator 501, may extend the wireless charging range (or area) of the wireless power transmission device 500. For example, when detached from the first resonator 501, the second resonator 502 may be used as a relay to intermediate wireless power transmission to an electronic device.

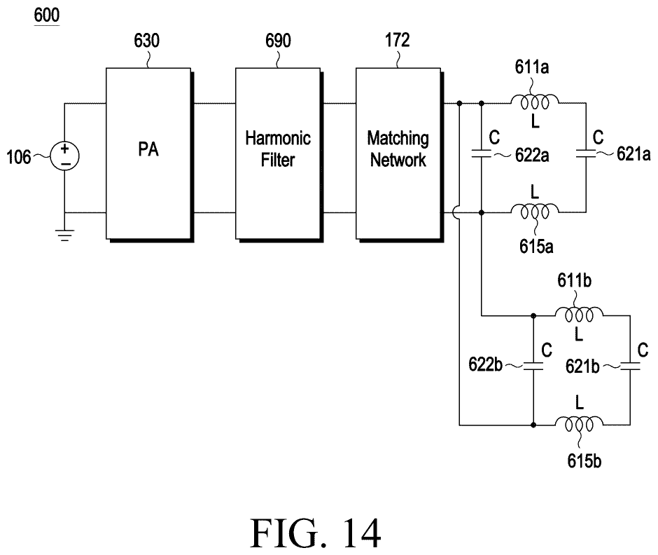

FIG. 13 is an exploded perspective view of a wireless power transmission device, according to an embodiment of the disclosure. FIG. 14 is a circuit diagram of a wireless power transmission device, according to an embodiment of the disclosure.

The embodiments of FIGS. 13 and 14 may be combined with the embodiments of FIGS. 1A to 12 or the embodiments of FIGS. 15 to 18.

Referring to FIGS. 13 and 14, the wireless power transmission device 600 may include a resonator 601 that comprises at least one coil 610 and at least one capacitor 620.

According to an embodiment, the at least one coil 610 may include an upper coil (e.g., a first upper coil 611a, a second upper coil 615a) and a lower coil (e.g., a first lower coil 611b, a second lower coil 615b). For example, the first and second upper coils 611a and 615a and the first and second lower coils 611b and 615b may be configured to be coupled to each other. When the first and second upper coils 611a and 615a and the first and second lower coils 611b and 615b are coupled, an internal space may be formed between the first and second upper coils 611a and 615a and the first and second lower coils 611b and 615b to accommodate a power transmission circuit 630 or electrical components.

According to an embodiment, the upper coil may include an upper first coil 611a and an upper second coil 615a. According to an embodiment, the lower coil may include a lower first coil 611b and a lower second coil 615b.

According to an embodiment, the at least one capacitor 620 may include an upper capacitor disposed in the first and second upper coils 611a and 615a and a lower capacitor disposed in the first and second lower coils 611b and 615b.

According to an embodiment, the upper capacitor may include a first upper capacitor 621a and a second upper capacitor 622a spaced apart from the first upper capacitor 621a. According to an embodiment, the lower capacitor may include a first lower capacitor 621b and a second lower capacitor 622b spaced apart from the first lower capacitor 621b.

FIG. 14 is a circuit diagram of the wireless power transmission device 600 of FIG. 13.

Referring to FIG. 14, the wireless power transmission device 600 may include a power transmission circuit 630 that receives power (or supplied power) provided by a power source 106 (e.g., the power source 106 of FIG. 2A).

According to an embodiment, the power transmission circuit 630 may include a power amplifier (PA).

According to an embodiment, the wireless power transmission device 600 may include a harmonic filter 690 to remove and/or reduce harmonic waves (e.g., harmonics) of the circuit of the wireless power transmission device 600, or a matching circuit 172 (e.g., the matching circuit 172 of FIG. 2B) (or a matching network). According to an embodiment, the first and second upper capacitors 621a and 622a and the first and second upper coils 611a and 615a may be arranged in series. The first and second lower capacitors 621b and 622b and the first and second lower coils 611b and 615b may also be arranged in series. According to an embodiment, the first and second upper capacitors 621a and 622a and the first and second upper coils 611a and 615a may be arranged in parallel with the first and second lower capacitors 621b and 622b and the first and second lower coils 611b and 615b with reference to the power source 106.

Referring to FIGS. 13 and 14, the first and second upper capacitors 621a and 622a and the first and second upper coils 611a and 615a may be defined as an upper resonator, and the first and second lower capacitors 621b and 622b and the first and second lower coils 611b and 615b may be defined as a lower resonator.

According to an embodiment, the radio frequency band output through the upper resonator, which includes the first and second upper capacitors 621a and 622a and the first and second upper coils 611a and 615a, may be tuned as described below. For example, when the upper resonator and the lower resonator are separated, the inductance value of the first and second upper coils 611a and 615a of the upper resonator may be represented as an equation similar to Equation 1.

$${L}_{tx}^{′} = \frac{2 {L}_{tx}}{K} \qquad [ Equation 1 ]$$

$${L}_{tx} = ( 1 + K ) \times \frac{{L}_{tx}^{′}}{2} \qquad [ Equation 2 ]$$

Referring to Equations 1 and 2, L′ₜₓ may represent the inductance value of the first and second upper coils 611a and 615a in a state where the upper resonator is separated from the lower resonator. In addition, Lₜₓ in Equations 1 and 2 may represent the inductance value of at least one coil (e.g., at least one coil 410 including the first coil 411 and the second coil 415 of FIG. 9) in a state where the upper resonator and the lower resonator are not separated (e.g., a state as shown in FIG. 9). Furthermore, K may represent a magnetic coupling coefficient between the upper resonator and the lower resonator. The magnetic coupling coefficient K may have a value of one (1) in a state where the upper resonator and the lower resonator are not separated (e.g., a state as shown in FIG. 9) and may have a value less than one (1) in a state where the upper resonator and the lower resonator are separated (e.g., as shown in FIG. 13). For example, as the distance (or gap) by which the upper resonator and the lower resonator are separated increases, the value of K may decrease.

Furthermore, in a state where the upper resonator and the lower resonator are separated, the capacitance value of the first and second upper capacitors 621a and 622a of the upper resonator may be represented as an equation similar to Equation 3.

$${C}_{p a r a l l e l}^{′} = \frac{{C}_{p a r a l l e l}}{2} \qquad [ Equation 3 ]$$

Referring to Equation 3, C′ₚₐᵣₐₗₗₑₗ may represent the capacitance value of the first and second upper capacitors 621a and 622a in a state where the upper resonator is separated from the lower resonator (e.g., as shown in FIG. 13). In addition, Cₚₐᵣₐₗₗₑₗ may represent the capacitance value of the first capacitor (e.g., at least one capacitor 420 of FIG. 9) in a state where the upper resonator and the lower resonator are not separated (e.g., a state as shown in FIG. 9).

In a state where the upper resonator and the lower resonator are not separated (e.g., a state as shown in FIG. 9), the resonant frequency of the resonator may be represented as an equation similar to Equation 4.

$${C}_{p a r a l l e l} = \frac{1}{( {w}^{2} \times {L}_{tx} )} \qquad [ Equation 4 ]$$

Through the inductance values and capacitance values derived from Equations 1 to 3, the resonant frequency of the resonator may be calculated. The wireless power transmission device 600 may tune the resonant frequency w of the coupled resonator by adjusting the distance (or gap) separated between the upper resonator and the lower resonator to control the magnetic coupling coefficient K. For example, when the upper resonator is arranged to be spaced apart from the lower resonator by a certain distance, the frequency band of the wireless power (e.g., power for wirelessly charging an electronic device) output from the coupled resonator may be tuned to 6.78 MHz.

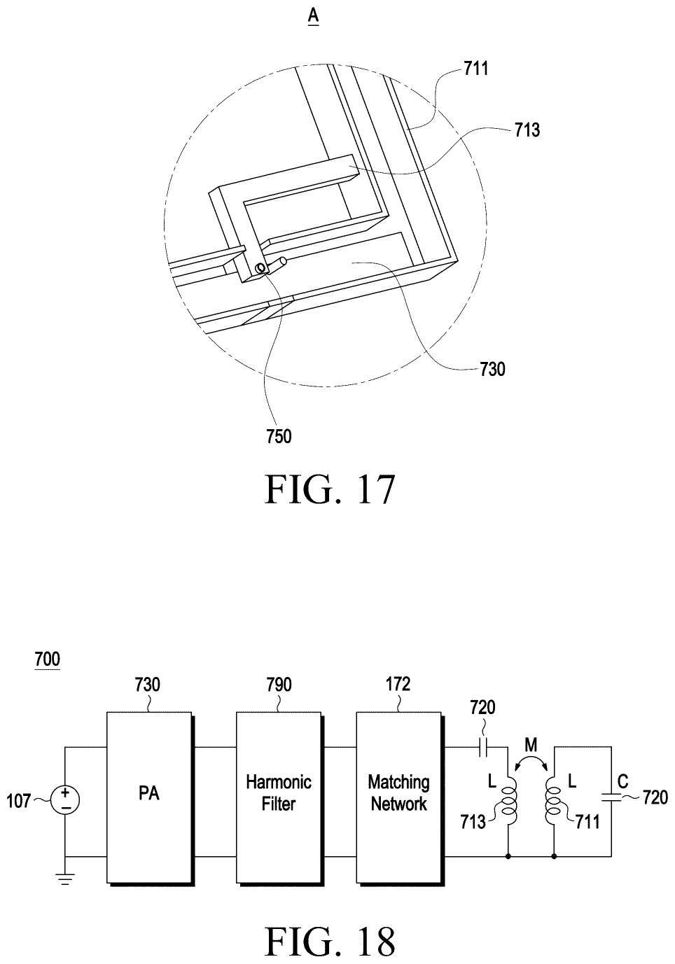

FIG. 15 is a perspective view of a wireless power transmission device, according to an embodiment of the disclosure. FIG. 16 is an exploded view of a wireless power transmission device, according to an embodiment of the disclosure. FIG. 17 is an enlarged view of part A of FIG. 16, according to an embodiment of the disclosure. FIG. 18 is a circuit diagram of a wireless power transmission device, according to an embodiment of the disclosure.

The embodiments of FIGS. 15 to 18 may be combined with the embodiments of FIGS. 1A to 14.

Referring to FIGS. 15 to 18, the wireless power transmission device 700 may include a resonator 701 that comprises at least one coil 710 and at least one capacitor 720.

According to an embodiment, the at least one coil 710 may include a first coil 711 and a second coil 713. According to an embodiment, the first coil 711 may be provided in a ring-shaped or loop-shaped form however, the present disclosure is not limited thereto. According to an embodiment, the first coil 711 may include an internal space 712.

According to an embodiment, the second coil 713 may be disposed inside a closed-loop shape formed by the first coil 711. According to an embodiment, the second coil 713 may have one end connected to an AC power output unit 750 and the other end connected to at least a portion of the first coil 711.

According to an embodiment, the AC power output unit 750 may be electrically connected to a power transmission circuit 730.

FIG. 18 is a circuit diagram of the wireless power transmission device 700 of FIGS. 15 to 17.

Referring to FIG. 18, the wireless power transmission device 700 may include a power transmission circuit 730 that receives power (or a power supply) provided by a power source 106 (e.g., the power source 106 of FIG. 2A).

According to an embodiment, the power transmission circuit 730 may include a power amplifier (PA).

According to an embodiment, the wireless power transmission device 700 may include a harmonic filter 790 to remove and/or reduce harmonic waves (e.g., harmonics) of the circuit of the wireless power transmission device 700, or a matching circuit 172 (e.g., the matching circuit 172 of FIG. 2B) (or a matching network).

According to an embodiment, the second coil 713 and the first coil 711 may be arranged to achieve mutual induction. According to an embodiment, the mutual inductance M may be adjusted by controlling the length of the second coil 713 disposed inside the closed-loop shape of the first coil 711.

The electronic device, according to various embodiments of the disclosure, may be one of various types of devices. The electronic devices may include, for example, a portable communication device (e.g., a smartphone), a computer device, a portable multimedia device, a portable medical device, a camera, a wearable device, or a home appliance. The electronic devices, according to an embodiment, are not limited to those described above.

It is to be understood that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in the various embodiments of the disclosure, the term “module” may include a unit implemented in hardware, software, or firmware, and may interchangeably be used with other terms, for example, “logic,” “logic block,” “portion,” or “circuitry”. A module may be a single integral component, or a minimum unit or portion thereof, adapted to perform one or more functions. For example, according to an embodiment, the module may be implemented in a form of an application-specific integrated circuit (ASIC).

Various embodiments of the disclosure may be implemented as software (e.g., a program) including one or more instructions that are stored in a storage medium (e.g., an internal memory or an external memory) that is leadable by a machine (e.g., the wireless power transmission device 100, the electronic device 150). For example, a processor (e.g., the processor 102, the processor 152) of the machine (e.g., the wireless power transmission device 100, the electronic device 150) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The storage medium leadable by the machine may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method may be included and provided in a computer program product. The computer program products may be traded as commodities between sellers and buyers. The computer program product may be distributed in the form of a machine-leadable storage medium (e.g., compact disc lead only memory (CD-ROM)), or be distributed (e.g., downloaded or uploaded) online via an application store (e.g., Play Store™), or between two user devices (e.g., smartphones) directly. If distributed online, at least portion of the computer program product may be temporarily generated or at least temporarily stored in the machine-leadable storage medium, such as memory of the manufacturer's server, a server of the application store, or a relay server.

According to various embodiments, each component (e.g., a module or a program) of the above-described components may include a single entity or multiple entities. Some of the plurality of entities may be separately disposed in different components. According to an embodiment, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

A wireless power transmission device for spatial wireless charging may include a coil for transmitting power and a power transmission circuit. The coil may be configured to generate a magnetic field to transmit wireless charging power for charging an electronic device located around the wireless power transmission device.

When the power transmission circuit is positioned far from the coil, loss may occur in the output of the coil, making it necessary to place the power transmission circuit adjacent to the coil.

However, when the power transmission circuit is positioned adjacent to the coil, metal components included in the power transmission circuit may cause loss in the output of the coil. In addition, components of the power transmission circuit (e.g., communication components or sensors) may generate noise due to the magnetic field of the coil.

However, the problems to be solved by the disclosure are not limited to those mentioned above and may be defined in various ways without departing from the spirit and scope of the disclosure.

According to an embodiment of the disclosure, a wireless power transmission device including a resonator structure may reduce losses in a magnetic field generated by the coil.

The effects obtainable from the disclosure are not limited to the effects mentioned above, and other effects not explicitly described may become apparent to those skilled in the art to which the disclosure pertains from the following description.

According to an embodiment of the disclosure, a wireless power transmission device 200 may include a resonator 201 comprising at least one coil 210 and at least one capacitor 220, an internal space 212 formed inside the at least one coil, and a power transmission circuit 230 disposed in the internal space.

According to an embodiment, the wireless power transmission device 200 may further include a DC power supply unit 340 for applying DC power to the power transmission circuit, and an AC power output unit 350 for applying AC power output from the power transmission circuit to the at least one coil.

According to an embodiment, the DC power supply unit may be positioned adjacent to the at least one capacitor.

According to an embodiment, the wireless power transmission device 200 may further include a control circuit 370 positioned adjacent to the AC power output unit.

According to an embodiment, the wireless power transmission device 200 may further include at least one antenna 380 disposed in the control circuit.

According to an embodiment, the at least one capacitor 420 may include a first capacitor 421 and a second capacitor 422 spaced apart from the first capacitor 421.

According to an embodiment, the first capacitor 421 may be positioned adjacent to the DC power supply unit 440, and the second capacitor 422 may be positioned adjacent to the AC power output unit 450.

According to an embodiment, the wireless power transmission device 200 may further include a spacer 418 disposed in the internal space and configured to separate the power transmission circuit from the at least one coil.

According to an embodiment, the wireless power transmission device 200 may further include a detachable resonator 502 detachably coupled to the resonator 501.

According to an embodiment, the at least one coil 610, 710 may include a first coil 611a, 615a, 711 and a second coil 611b, 615b, 713, at least a portion of which is coupled to the first coil.

According to an embodiment, the internal space may be a space formed between the first coil and the second coil in a state where the first coil 611 and the second coil 612 are coupled.

According to an embodiment, the at least one capacitor may include a first capacitor disposed in the first coil and a second capacitor disposed in the second coil.

According to an embodiment, the first capacitor and the second capacitor may be arranged in parallel.

According to an embodiment, the first coil 711 may include a closed-loop shape, and the second coil 713 may be disposed inside the closed-loop shape of the first coil.

According to an embodiment, the second coil may be configured to mutually induce with the first coil to generate an electromotive force in the first coil.

According to an embodiment of the disclosure, the wireless power transmission device 200 may include a resonator 201 comprising at least one coil 210 and at least one capacitor 220, an internal space 212 formed inside the at least one coil, and a power transmission circuit 230 disposed in the internal space, wherein the at least one coil may form at least a portion of a closed-loop shape.

According to an embodiment, the wireless power transmission device 200 may further include a harmonic filter 490 disposed in the internal space 412 and a matching circuit 172 disposed in the internal space.

According to an embodiment, the power transmission circuit 430 may include a first power transmission circuit 431 and a second power transmission circuit 432 arranged in parallel with the first power transmission circuit.

According to an embodiment, the wireless power transmission device 200 may further include a DC power supply unit 340 for applying DC power to the power transmission circuit and an AC power output unit 350 for applying AC power output from the power transmission circuit to the at least one coil.

According to an embodiment, the wireless power transmission device 200 may further include a cooling fan 390 disposed in the internal space.

As described above, while the detailed descriptions of the disclosure have been described with reference to specific embodiments, it is to be apparent to those skilled in the art that various modifications in form and detail may be made without departing from the scope of the disclosure.

What is claimed is:

1. A wireless power transmission device, comprising:
a resonator configured to transmit wireless power to another device and comprising at least one coil and at least one capacitor;
an internal space formed inside the at least one coil, and
a power transmission circuit disposed in the internal space.

2. The wireless power transmission device of claim 1, further comprising:
a direct current (DC) power supply configured to supply DC power to the power transmission circuit; and
an alternating current (AC) power output configured to supply AC power output from the power transmission circuit to the at least one coil.

3. The wireless power transmission device of claim 2, wherein the DC power supply is disposed adjacent to the at least one capacitor.

4. The wireless power transmission device of claim 2, further comprising:
a control circuit disposed adjacent to the AC power output.

5. The wireless power transmission device of claim 4, further comprising:
at least one antenna disposed in the control circuit.

6. The wireless power transmission device of claim 2, wherein the at least one capacitor comprises a first capacitor and a second capacitor spaced apart from the first capacitor.

7. The wireless power transmission device of claim 6,
wherein the first capacitor is disposed adjacent to the DC power supply, and
wherein the second capacitor is disposed adjacent to the AC power output.

8. The wireless power transmission device of claim 1, further comprising:
a spacer disposed in the internal space and configured to separate the power transmission circuit from the at least one coil.

9. The wireless power transmission device of claim 1, further comprising:
a detachable resonator removably coupled to the resonator.

10. The wireless power transmission device of claim 1, wherein the at least one coil comprises a first coil and a second coil at least partially coupled to the first coil.

11. The wireless power transmission device of claim 10, wherein the internal space is formed between the first coil and the second coil in a state where the first coil and the second coil are coupled.

12. The wireless power transmission device of claim 11, wherein the at least one capacitor comprises a first capacitor disposed in the first coil and a second capacitor disposed in the second coil.

13. The wireless power transmission device of claim 12, wherein the first capacitor and the second capacitor are disposed in parallel.

14. The wireless power transmission device of claim 10,
wherein the first coil comprises a closed-loop shape, and
wherein the second coil is disposed inside the closed-loop shape of the first coil.

15. The wireless power transmission device of claim 10, wherein the second coil is configured to be mutually induced with the first coil to generate an induced electromotive force in the first coil.

16. A wireless power transmission device, comprising:
a resonator configured to transmit wireless power to another device and comprising at least one coil and at least one capacitor;
an internal space formed inside the at least one coil, and
a power transmission circuit disposed in the internal space,
wherein the at least one coil has at least a portion forming a closed-loop shape.

17. The wireless power transmission device of claim 16, further comprising:
a harmonic filter disposed in the internal space and a matching circuit disposed in the internal space.

18. The wireless power transmission device of claim 16, further comprising:
a first power transmission circuit and a second power transmission circuit arranged in parallel with the first power transmission circuit.

19. The wireless power transmission device of claim 16, further comprising:
a DC power supply for applying DC power to the power transmission circuit and an AC power output for applying AC power output from the power transmission circuit to the at least one coil.

20. The wireless power transmission device of claim 16, further comprising:
a cooling fan disposed in the internal space.
